(19) United States
(12) Patent Application Publication
(10) Pub. No.: US 2026/0293497 A1
(43) Pub. Date: Sep. 24, 2026

(54) ELECTRONIC APPARATUS AND METHOD FOR MANUFACTURING THE SAME

(71) Applicant: Samsung Display Co., LTD., Yongin-si (KR)

(72) Inventors: JAEYOUNG JANG, Yongin-si (KR); YUNOH NAM, Yongin-si (KR); CHANHEE PARK, Yongin-si (KR)

(21) Appl. No.: 19/550,977

(22) Filed: Feb. 26, 2026

(30) Foreign Application Priority Data
Mar. 18, 2025 (KR) 10-2025-0034908

(51) Int. Cl. H10K 59/80; H10K 59/12; H10K 59/95

(52) U.S. Cl. CPC H10K 59/873; H10K 59/1201; H10K 59/95

(57) ABSTRACT

An electronic apparatus includes: a display module divided into a first region including a pixel, a second region bent with respect to a virtual axis extending in a first direction, and a third region where a driving chip electrically connected to the pixel is mounted, a flexible circuit board disposed in at least a portion of the third region of the display module and connected to the display module, and a cover layer which covers the driving chip. A depression portion corresponding to the driving chip is defined in a surface of the cover layer facing the driving chip.

### CROSS-REFERENCE TO RELATED APPLICATION

This application claims priority to Korean Patent Application No. 10-2025-0034908, filed on Mar. 18, 2025, and all the benefits accruing therefrom under 35 U.S.C. §119, the content of which in its entirety is herein incorporated by reference.

### BACKGROUND

The present disclosure herein relates to an electronic apparatus and a method for manufacturing an electronic apparatus, and more particularly, to an electronic apparatus with improved reliability and a method for manufacturing an electronic apparatus.

Various electronic apparatuses used for multimedia apparatuses such as televisions, mobile phones, tablet computers, navigation systems, and game consoles are being developed. The electronic apparatuses include a display panel which displays an image, and circuit boards which are coupled to the display panel and provide a driving signal to the display panel. The display panel includes a display portion for displaying an image, and panel pads disposed outside the panel so as to provide the driving signal to the display portion.

A display module included in the electronic apparatus includes a plurality of pixels for displaying an image and a driving chip for driving the pixels. The pixels are disposed in a display region of the display module, and the driving chip is disposed in a peripheral region, of the display module, which surrounds the display region. In the display module, a bending region is defined between the driving chip and the display region, and the bending region is bent, so that the driving chip is disposed under the display module.

### SUMMARY

The present disclosure provides an electronic apparatus with reliability by reducing air bubbles which are generated by a cover layer disposed on a driving chip, and a method for manufacturing an electronic apparatus.

An embodiment of the invention provides an electronic apparatus including a display module divided into a first region including a pixel, a second region bent with respect to a virtual axis extending in a first direction, and a third region where a driving chip electrically connected to the pixel is mounted, a flexible circuit board disposed in at least a portion of the third region of the display module and connected to the display module, and a cover layer configured to cover the driving chip. A depression portion corresponding to the driving chip is defined in a surface of the cover layer facing the driving chip.

In an embodiment of the invention, a method for manufacturing an electronic apparatus includes forming a display module which is divided into a first region including a pixel, a second region bent with respect to a virtual axis extending in a first direction, and a third region where a driving chip electrically connected to the pixel is mounted, forming a flexible circuit board electrically connected to the display module on one side of the third region of the display module, disposing the flexible circuit board on a rear surface of the display module by bending the second region, and disposing, on the driving chip, a cover layer which covers the driving chip. A depression portion corresponding to the driving chip is defined in a surface of the cover layer facing the driving chip.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a block diagram of an electronic apparatus according to an embodiment of the invention;

FIG. 2 shows schematic diagrams of various electronic apparatuses according to embodiments;

FIG. 3 is a perspective view of an electronic apparatus according to an embodiment of the invention;

FIG. 4 is an exploded perspective view of an electronic apparatus according to an embodiment of the invention;

FIG. 5 is a cross-sectional view of a display module according to an embodiment of the invention taken along line I-I' of FIG. 4;

FIG. 6 is a plan view of a display panel according to an embodiment of the invention;

FIG. 7 is a plan view of an input sensing layer according to an embodiment of the invention;

FIG. 8 is an enlarged cross-sectional view of a portion of an electronic apparatus according to an embodiment of the invention;

FIGS. 9A to 9D are process diagrams illustrating a part of a method for manufacturing an electronic apparatus according to an embodiment of the invention; and

FIGS. 10A to 10D are process diagrams illustrating a part of a method for manufacturing an electronic apparatus according to another embodiment of the invention.

### DETAILED DESCRIPTION

The invention may be implemented in various modifications and have various forms, and specific embodiments are illustrated in the drawings and described in detail in the text. It is to be understood, however, that the invention is not intended to be limited to the particular forms disclosed, but on the contrary, is intended to cover all modifications, equivalents, and alternatives falling within the spirit and scope of the invention.

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the invention. Similarly, a second element could be termed a first element. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms have relative concepts and are described on the basis of the directions indicated in the drawings.

It will be further understood that the terms "comprises, includes, has" and/or "comprising, including, having", when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

In this specification, when an element is referred to as being "directly disposed on" another layer, film, region, board, etc., there may be no intervening layer, film, region, board, etc., present. For example, the wording “directly disposed” may indicate that two layers or two members are disposed without using an additional member, such as an adhesive member, between the two layers or two members.

Unless otherwise defined, all terms (including technical and scientific terms) used herein have the same meaning as commonly understood by one of ordinary skills in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to an embodiment is described with reference to the drawings.

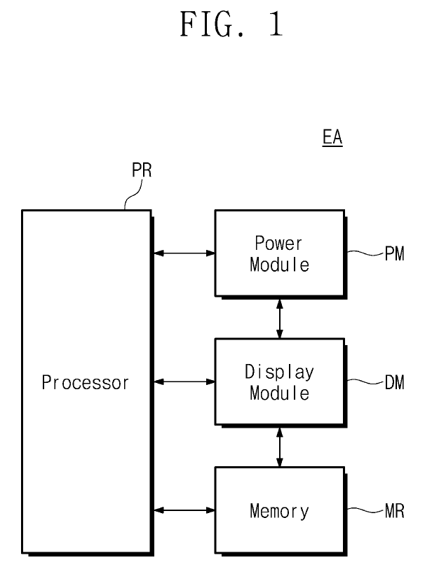

FIG. 1 is a block diagram of an electronic apparatus according to an embodiment of the invention.

Referring to FIG. 1, an electronic apparatus ED according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

In the memory MR, data information for an operation of the processor PR or the display module DM may be stored. When the processor PR executes an application stored in the memory MR, an image data signal and/or an input control signal may be transmitted to the display module DM, and the display module DM may process the received signal and output image information through a display screen. The display module DM may include a display panel for displaying an image.

The power module PM may include a power conversion module. The power conversion module may convert the power provided by a power supply module such as a power adapter or battery unit, and generate power for an operation of the electronic apparatus ED.

At least one of the respective components of the electronic apparatus ED described above may be included within a display module according to embodiments to be described later and a display device, including the same, according to an embodiment. In addition, some of individual modules functionally included within one module may be included within the display device, and others may be provided separately from the display device. For example, the display device may include the display module DM, and the processor PR, the memory MR, and the power module PM may be provided as a form of another device within the electronic apparatus ED other than the display device.

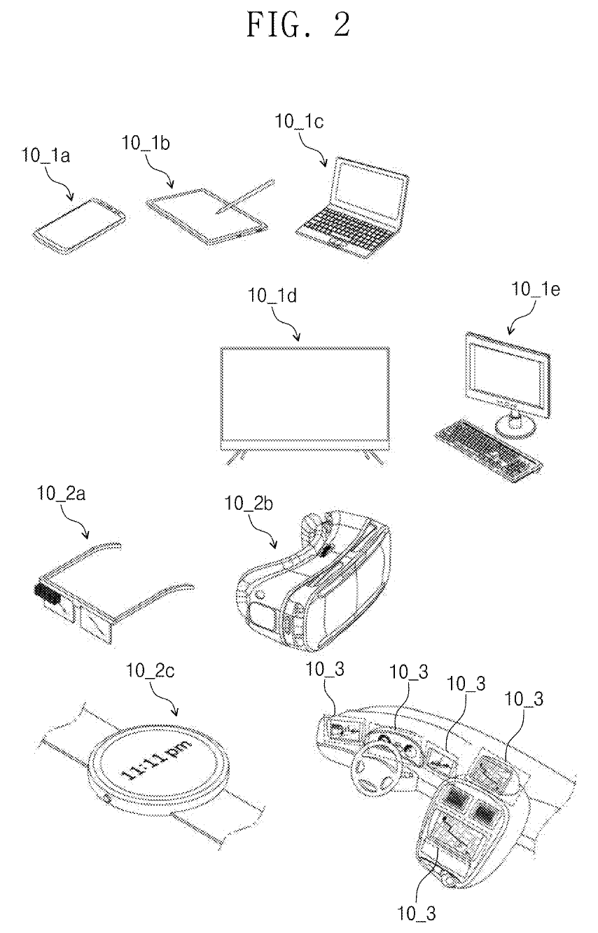

FIG. 2 shows schematic diagrams of various electronic apparatuses according to embodiments.

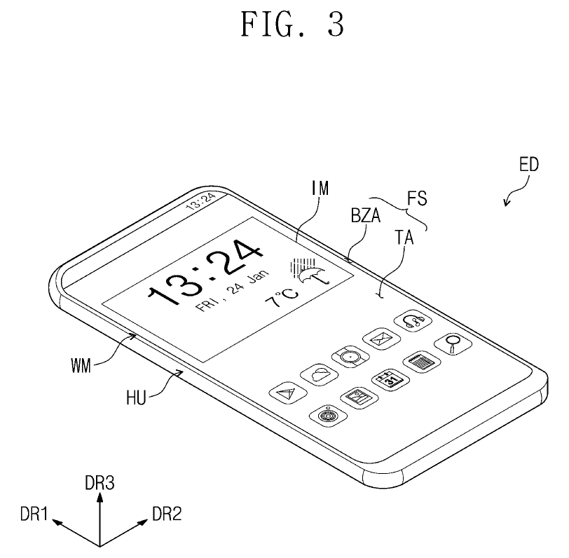

Referring to FIG. 2, various electronic apparatuses including a display module according to an embodiment may include not only an electronic apparatus for displaying an image such as a smart phone ED_1a, a tablet PC ED_1b, a laptop computer ED_1c, a TV ED_1d, and a monitor ED_1e for a desk, but also a wearable electronic apparatus such as smart glasses ED_2a, a head-mounted display ED_2b, and a smart watch ED_2c, and an electronic apparatus ED_3 for vehicles such as a room mirror display and a center information display (CID), which is disposed on a car’s instrument cluster, center fascia, and dashboard. The electronic apparatus ED according to an embodiment of the invention may be a mobile phone as illustrated in FIG. 3, but is not limited thereto.

FIG. 3 is a perspective view of an electronic apparatus according to an embodiment of the invention. FIG. 4 is an exploded perspective view of an electronic apparatus according to an embodiment of the invention.

An electronic apparatus ED may be activated in response to an electrical signal. The electronic apparatus ED may include various embodiments. For example, the electronic apparatus ED may be applied to an electronic apparatus such as a mobile phone, smart watch, tablet PC, laptop computer, computer, and smart television. A display device according to the invention is not limited to the above examples, and may also be applied to another electronic apparatus unless deviating from the idea of the invention. In this embodiment, the electronic apparatus ED is exemplarily illustrated as a mobile phone.

The electronic apparatus ED may display an image IM toward a third direction DR3 on a display surface FS that is parallel to each of a first direction DR1 and a second direction DR2. The display surface FS where the image IM is displayed may correspond to a front surface of a display device DD. The image IM may include a static image as well as a dynamic image. In FIG. 3, a clock and icons are illustrated as one example of the image IM.

In this embodiment, a front surface (or top surface) and a rear surface (or bottom surface) of each member are defined based on a direction where the image IM is displayed. The front surface and the rear surface are opposed to each other in the third direction DR3, and a normal direction of each of the front surface and the rear surface may be parallel to the third direction DR3. A spaced distance between the front surface and the rear surface in the third direction DR3 may correspond to a thickness of the display device DD in the third direction DR3. In this specification, the wording “in a plan view” may mean “when viewed in the third direction DR3 (i.e., thickness direction of the electronic apparatus ED)”. The directions which are indicated by the first to third directions DR1, DR2, and DR3, respectively, may have a relative concept and may thus be changed to other directions.

The electronic apparatus ED may sense an external input applied from the outside. The external input may include various types of inputs provided from the outside of the electronic apparatus ED. For example, the external input may include not only a touch by a user’s body part such as a hand but also an external input (for example, hovering) applied by approaching or becoming adjacent to the electronic apparatus ED at a distance. In addition, the external input may have various types such as force, pressure, temperature, or light.

The electronic apparatus ED may include a window WM and a housing HU. The window WM and the housing HU may be coupled and may constitute an exterior of the electronic apparatus ED.

The window WM may be divided into a transmission region TA and a bezel region BZA. A front surface of the electronic apparatus ED may correspond to the transmission region TA and the bezel region BZA of the window WM.

The transmission region TA may be a region where the image IM is displayed. The transmission region TA may be an optically transparent region. A user may view the image IM through the transmission region TA.

In this embodiment, the transmission region TA is illustrated as a quadrangular shape with rounded corners. However, this is exemplarily illustrated, and the transmission region TA may have various shapes and is not limited to any one embodiment.

The bezel region BZA may be a region having relatively lower light transmittance than the transmission region TA. For example, the bezel region BZA may be provided as a region where a material including a color is printed.

The bezel region BZA may be a region adjacent to the transmission region TA. The bezel region BZA may surround the transmission region TA. Accordingly, a shape of the transmission region TA may be substantially defined by the bezel region BZA. However, this is exemplarily illustrated, and the bezel region BZA may be disposed adjacent to only one side of the transmission region TA, and may be omitted.

Referring to FIGS. 3 and 4 together, the electronic apparatus ED may include a display device DD, an electronic module EM, a power module PM, and a housing HU. The electronic apparatus ED is briefly illustrated in FIG. 4, and the electronic apparatus ED may further include a mechanical structure (for example, a hinge) for controlling an operation (for example, folding or rolling) of the display device DD.

The display device DD includes a window WM, an optical film LF, a display module DM, a lower member LM, a driving chip DIC, and a flexible circuit board FCB.

The window WM may be disposed on the display module DM. The window WM may protect the display module DM. The window WM may include an optically transparent material. For example, the window WM may include glass, sapphire, plastic, or the like. An image provided from the display module DM may be provided to a user through the window WM.

The window WM may have a single- or multi-layered structure. For example, the window WM may include a plurality of plastic films which are coupled to each other, or a glass substrate and a plastic film which are coupled to each other.

The optical film LF may be disposed under the window WM. The optical film LF may reduce reflectance for external light incident from an upper side of the window WM. The optical film LF may include a phase retarder and a polarizer. The phase retarder may be a film type or a liquid crystal coating type, and may include a λ phase retarder and/or a λ phase retarder. The polarizer may also be a film type or a liquid crystal coating type. The film type may include a stretchable synthetic resin film, and the liquid crystal coating type may include liquid crystals arranged in an arrangement. The phase retarder and the polarizer may be implemented as a single polarizing film. The optical film LF may further include a protective film disposed on or under the polarizing film.

The display module DM may be disposed under the optical film LF. The display module DM may include a front surface IS having an active region AA and a peripheral region NAA. The active region AA may be activated in response to an electrical signal. In this embodiment, the active region AA may be a region where the image IM is displayed, and simultaneously a region where an external input is sensed.

The transmission region TA may overlap at least a portion of the active region AA. Accordingly, a user may view the image IM or provide an external input, through the transmission region TA. However, this is exemplarily illustrated, and within the active region AA, the region where the image IM is displayed and the region where the external input is sensed may be separated from each other, and the above configuration is not limited to any one embodiment.

The peripheral region NAA may be a region covered by the bezel region BZA. The peripheral region NAA may be adjacent to the active region AA. The peripheral region NAA may surround the active region AA. A driving circuit or driving wiring for driving the active region AA may be disposed in the peripheral region NAA.

According to the invention, the display module DM may include a first region A1, a second region A2, and a third region A3 which are arranged in the first direction DR1. The first region A1 may include the active region AA. In this specification, the second region A2, the third region A3, and a remaining region other than the active region AA in the first region A1 may correspond to the peripheral region NAA.

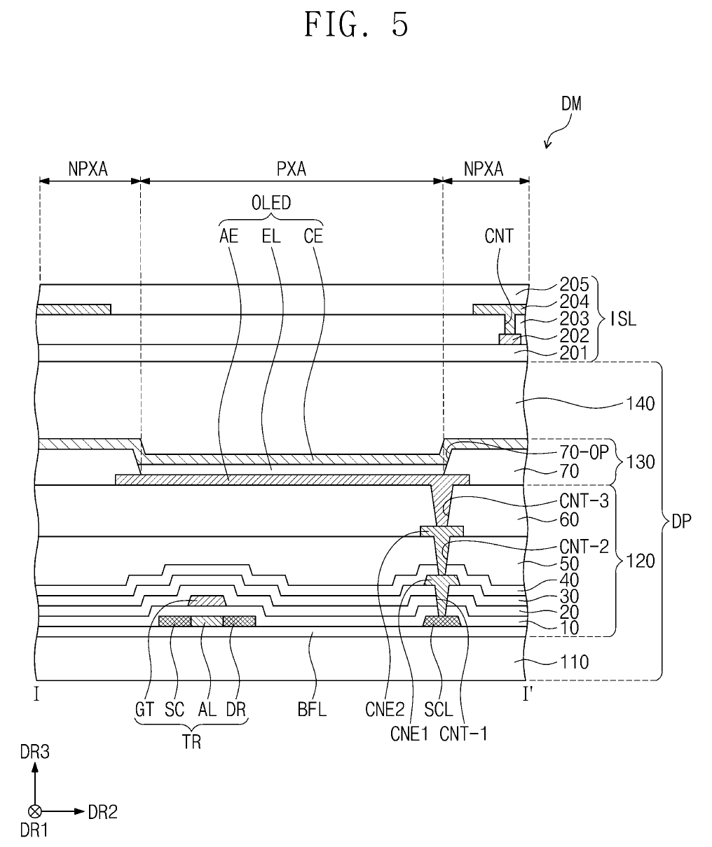

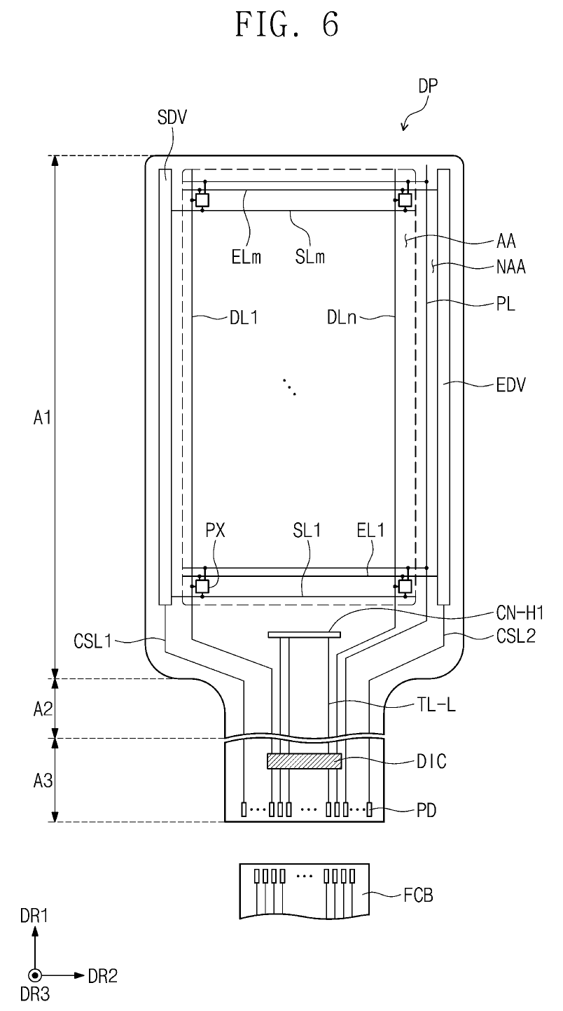

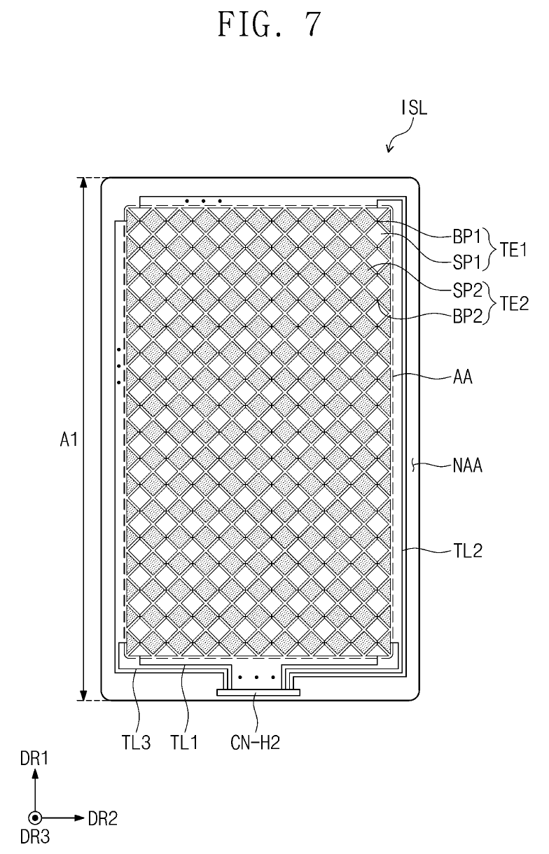

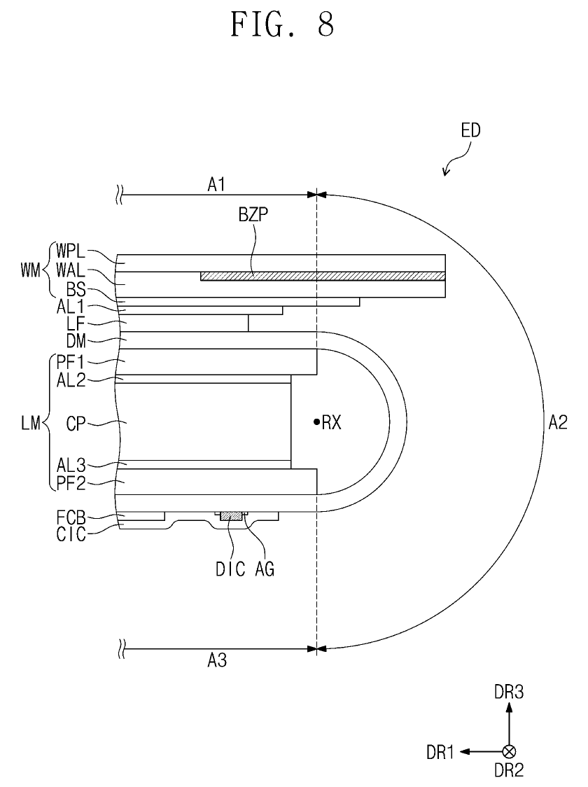

The driving chip DIC is mounted on the third region A3, and the third region A3 may include pads PD (see FIG. 6) disposed adjacent to an end. The flexible circuit board FCB may be disposed on the pads PD of the third region A3 to be electrically connected to the display module DM. Although not illustrated, the electronic apparatus ED according to the invention may further include a cover layer CIC (see FIG. 8) disposed on the display module DM. A detailed description thereof will be given later.

According to the invention, the second region A2 of the display module DM may be bent such that the third region A3 faces a rear surface of the display module DM. Here, the driving chip DIC and the flexible circuit board FCB may be disposed under the first region A1. The cover layer CIC may be bent together when the second region A2 of the display module DM is bent.

The display module DM may include a display panel DP and an input sensing layer ISL. The display panel DP according to an embodiment of the invention may be a liquid crystal display panel or an emissive display panel, but is not particularly limited. For example, the emissive display panel may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, or the like.

The display panel DP may be flexible. The wording “flexible” may may indicate a bendable property, and may include all structures spanning from a structure which is completely foldable to a structure which is partially bendable. For example, the display panel DP may be a curved display panel or a foldable display panel, but is not limited thereto, and the display panel DP may be rigid in another embodiment.

The input sensing layer ISL may be disposed on the display panel DP. As illustrated in FIG. 4, the input sensing layer ISL may be directly disposed on the display panel DP. That is, the input sensing layer ISL may be formed on the display panel DP through a continuous process, and an adhesive film may not be disposed between the input sensing layer ISL and the display panel DP. However, the invention is not limited thereto, and the adhesive film may be disposed between the input sensing layer ISL and the display panel DP in another embodiment. The input sensing layer ISL may be manufactured through a separate process from the display panel DP, and then fixed on an upper surface of the display panel DP by the adhesive film.

The input sensing layer ISL may sense an external input applied from the outside. As mentioned above, the input sensing layer ISL may sense an external input provided onto the window WM.

The flexible circuit board FCB may be disposed at one side of the display panel DP. Specifically, the flexible circuit board FCB may be disposed on the display panel DP while overlapping the end of the third region A3 of the display panel DP. In this embodiment, one flexible circuit board FCB is illustrated, but is not limited thereto. The flexible circuit board FCB may be provided in plurality in another embodiment.

The driving chip DIC may be disposed in the third region A3 of the display module DM. The driving chip DIC may be disposed on the display panel DP. The driving chip DIC may include driving elements for driving pixels of the display panel DP. The driving chip DIC may include a driving circuit, and the driving circuit may be composed of an integrated circuit. The driving circuit may include a driving controller, a data driver, a voltage generator, or the like.

Although not illustrated, the flexible circuit board FCB may further include an input circuit board electrically connected to the input sensing layer ISL. The input circuit board may connect the input sensing layer ISL and a main circuit board MB. In this embodiment, the input circuit board may be provided as a flexible circuit film, and may connect the input sensing layer ISL and the main circuit board MB. The input circuit board provides an electrical signal for driving the input sensing layer ISL to the input sensing layer ISL. The electrical signal may be generated on the input circuit board or may be generated on the main circuit board MB.

The lower member LM may be disposed under the display panel DP. The lower member LM may include a protective film for protecting the display panel DP, a support member for supporting the display panel DP, a digitizer, and the like.

The electronic module EM and the power module PM may be disposed under the display module DM. The electronic module EM and the power module PM may be electrically connected through a separate circuit board.

The power module PM may supply power for operations of the electronic apparatus ED. For example, the power module PM may include a typical battery module.

The electronic module EM may include a control module, a wireless communication module, an image input module, a sound input module, a sound output module, a memory, an external interface module, and the like. The electronic module EM may include the main circuit board, and the above modules may be mounted on the main circuit board, or may be electrically connected to the main circuit board through the flexible circuit board. The electronic module EM may be electrically connected to the power module PM.

Although not illustrated separately, the electronic apparatus ED may further include an electronic optical module. The electronic optical module may be an electronic component that receives or outputs an optical signal. The electronic optical module may include a camera module and/or a proximity sensor. The camera module may photograph an external image through a partial region of the display panel DP.

The housing HU illustrated in FIG. 4 may be coupled to the display device DD, particularly the window WM, to accommodate other modules above. The housing HU is illustrated as having an integrated shape, but is not limited thereto. The housing HU may include a plurality of portions (for example, a side edge portion and a bottom portion) coupled to each other in another embodiment. The housing HU may protect the display module DM accommodated in an internal space from an external impact, and may prevent foreign matters or moisture from infiltrating into the display module DM.

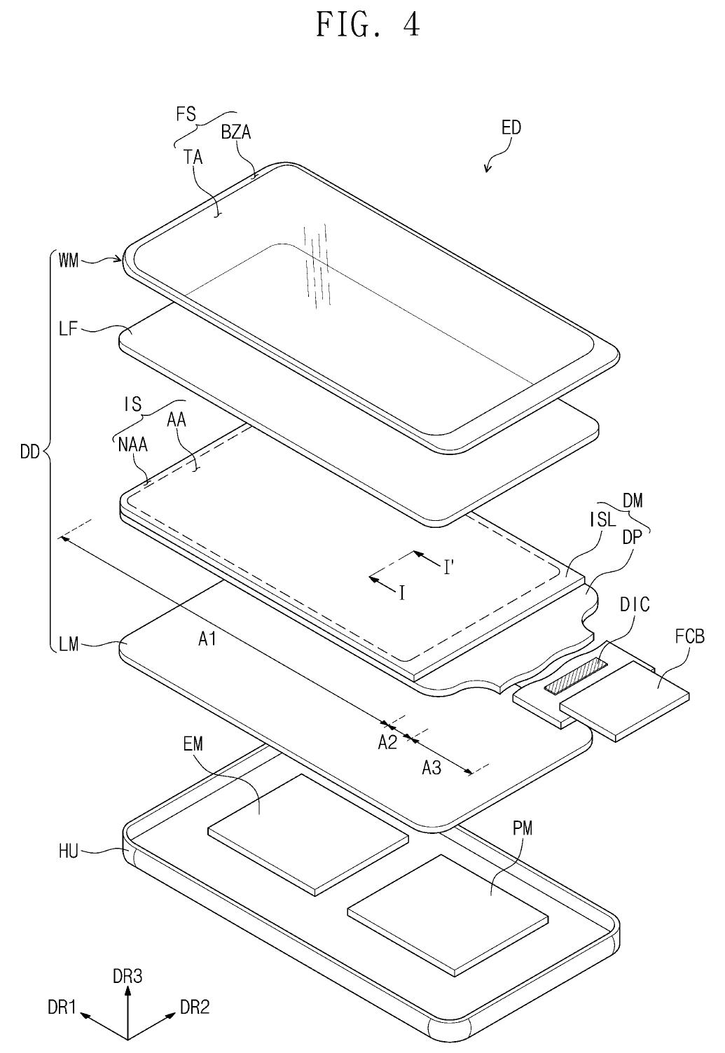

FIG. 5 is a cross-sectional view of a display module according to an embodiment of the invention taken along line I-I' of FIG. 4.

Referring to FIG. 5, a display module DM may include a display panel DP and an input sensing layer ISL disposed on the display panel DP. The display panel DP generates an image, and the input sensing layer ISL obtains coordinate information about an external input (for example, a touch event). Accordingly, the display module DM may display the image in response to an electrical signal, and may transmit/receive information about the external input.

The display panel DP may be a component which substantially generates an image. The display panel DP may be any one among an organic light-emitting display panel, a quantum-dot display panel, and an inorganic light-emitting display panel, and is not particularly limited.

The display panel DP may include a base layer 110, a circuit element layer 120, a light-emitting element layer 130, and an encapsulation layer 140. The base layer 110 may be a member providing a base surface where the circuit element layer 120 is disposed. The base layer 110 may be a glass substrate, metal substrate, polymer substrate, or the like. However, an embodiment is not limited thereto, and the base layer 110 may be an inorganic layer, organic layer, or composite material layer in another embodiment.

The base layer 110 may have a multi-layered structure. For example, the base layer 110 may include a first synthetic resin layer, a silicon oxide (SiOₓ) layer disposed on the first synthetic resin layer, an amorphous silicon (a-Si) layer disposed on the silicon oxide layer, and a second synthetic resin layer disposed on the amorphous silicon layer. The silicon oxide layer and the amorphous silicon layer may be referred to as a base barrier layer.

The first and second synthetic resin layers may each include a polyimide-based resin. In addition, the first and second synthetic resin layers may each include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a "~~based" resin may be considered as including a functional group of "~~".

The circuit element layer 120 may be disposed on the base layer 110. The circuit element layer 120 may include an insulation layer, a semiconductor pattern, a conductive pattern, a signal line, and the like. The insulation layer, a semiconductor layer, and a conductive layer may be formed on the base layer 110 through a method of coating, deposition, etc., and then the insulation layer, the semiconductor layer, and the conductive layer may be selectively patterned through multiple photolithography processes. Thereafter, the semiconductor pattern, the conductive pattern, and the signal line which are included in the circuit element layer 120 may be formed.

At least one inorganic layer may be formed on an upper surface of the base layer 110. The inorganic layer may include at least one among aluminum oxide, titanium oxide, silicon oxide, silicon nitride, silicon oxynitride, zirconium oxide, and hafnium oxide. The inorganic layer may be formed as multiple layers. The multiple inorganic layers may constitute a barrier layer and/or a buffer layer. In this embodiment, it is illustrated that the display panel DP includes a buffer layer BFL.

The buffer layer BFL may improve adhesion between the base layer 110 and the semiconductor pattern. The buffer layer BFL may include at least one among silicon oxide, silicon nitride, and silicon oxynitride. For example, the buffer layer BFL may include a structure where a silicon oxide layer and a silicon nitride layer are alternately stacked.

The semiconductor pattern may be disposed on the buffer layer BFL. The semiconductor pattern may include polysilicon. However, an embodiment is not limited thereto, and the semiconductor pattern may also include amorphous silicon, low temperature polycrystalline silicon, or an oxide semiconductor in another embodiment.

FIG. 5 illustrates only a portion of the semiconductor pattern, and the semiconductor pattern may further be disposed in another region. The semiconductor pattern may be arranged in accordance with a particular rule across pixels. The semiconductor pattern may have different electrical properties depending on whether to be doped or not. The semiconductor pattern may include a first region with high conductivity and a second region with low conductivity. The first region may be doped with an N-type dopant or a P-type dopant. A P-type transistor may include a region doped with the P-type dopant, and an N-type transistor may include a region doped with the N-type dopant. The second region may be an undoped region or a lightly doped region compared to the first region.

The conductivity of the first region may be greater than the conductivity of the second region, and the first region may substantially serve as an electrode or a signal line. The second region may substantially correspond to an active (or channel) of a transistor. In other words, a portion of the semiconductor pattern may be the active of the transistor, another portion may be a source or drain of the transistor, and still another portion may be a connection electrode or connection signal line.

The pixels may each have an equivalent circuit including seven transistors, one capacitor, and a light-emitting element, and an equivalent circuit diagram of the pixel may be deformed into various forms. FIG. 5 exemplarily illustrates one transistor TR and a light-emitting element OLED which are included in the pixel.

A source SC, an active AL, and a drain DR of the transistor TR may be formed from the semiconductor pattern. The source SC and the drain DR may extend in opposite directions from the active AL on a cross section, respectively.

FIG. 5 illustrates a portion of a connection signal wiring SCL formed from the semiconductor pattern. Although not illustrated separately, the connection signal wiring SCL may be connected to the drain DR of the transistor TR in a plan view.

A first insulation layer 10 may be disposed on the buffer layer BFL. The first insulation layer 10 may cover the semiconductor pattern while overlapping a plurality of pixels in common. The first insulation layer 10 may be an inorganic layer and/or an organic layer, and may have a single- or multi-layered structure. The first insulation layer 10 may include at least one among aluminum oxide, titanium oxide, silicon oxide, silicon nitride, silicon oxynitride, zirconium oxide, and hafnium oxide. In this embodiment, the first insulation layer 10 may be a single layer of silicon oxide. An insulation layer of the circuit element layer 120 to be described later as well as the first insulation layer 10 may be an inorganic layer and/or an organic layer, and may have a single- or multi-layered structure. The inorganic layer may include at least one of the aforementioned materials, but is not limited thereto.

A gate GT of the transistor TR is disposed on the first insulation layer 10. The gate GT may be a portion of a metal pattern. The gate GT overlaps the active AL. The gate GT may function as a mask in a process of doping the semiconductor pattern.

A second insulation layer 20 may be disposed on the first insulation layer 10, and may cover the gate GT. The second insulation layer 20 may overlap the pixels in common. The second insulation layer 20 may be an inorganic layer and/or an organic layer, and may have a single- or multi-layered structure. The second insulation layer 20 may include at least one among silicon oxide, silicon nitride, and silicon oxynitride. In this embodiment, the second insulation layer 20 may have a multi-layered structure including a silicon oxide layer and a silicon nitride layer.

A third insulation layer 30 may be disposed on the second insulation layer 20. The third insulation layer 30 may have a single- or multi-layered structure. For example, the third insulation layer 30 may have a multi-layered structure including a silicon oxide layer and a silicon nitride layer.

A first connection electrode CNE1 may be disposed on the third insulation layer 30. The first connection electrode CNE1 may be connected to the connection signal wiring SCL through a contact hole CNT-1 that penetrates the first, second, and third insulation layers 10, 20, and 30.

A fourth insulation layer 40 may be disposed on the third insulation layer 30. The fourth insulation layer 40 may be a single layer of silicon oxide. A fifth insulation layer 50 may be disposed on the fourth insulation layer 40. The fifth insulation layer 50 may be an organic layer.

A second connection electrode CNE2 may be disposed on the fifth insulation layer 50. The second connection electrode CNE2 may be connected to the first connection electrode CNE1 through a contact hole CNT-2 that penetrates the fourth insulation layer 40 and the fifth insulation layer 50.

A sixth insulation layer 60 may be disposed on the fifth insulation layer 50, and may cover the second connection electrode CNE2. The sixth insulation layer 60 may be an organic layer.

The light-emitting element layer 130 may be disposed on the circuit element layer 120. The light-emitting element layer 130 may include a light-emitting element. For example, the light-emitting element layer 130 may include an organic light-emitting material, quantum dots, quantum rods, a micro LED, or a nano LED. Hereinafter, the light-emitting element OLED is described as an organic light-emitting element as an example, but is not particularly limited thereto.

The light-emitting element OLED may include a first electrode AE, a light-emitting layer EL, and a second electrode CE. The first electrode AE may be disposed on the sixth insulation layer 60. The first electrode AE may be connected to the second connection electrode CNE2 through a contact hole CNT-3 that penetrates the sixth insulation layer 60.

A pixel-defining film 70 may be disposed on the sixth insulation layer 60, and may cover a portion of the first electrode AE. An opening 70-OP is defined in the pixel-defining film 70. The opening 70-OP of the pixel-defining film 70 exposes at least a portion of the first electrode AE.

The active region AA (see FIG. 4) may include a light-emitting region PXA and a non-light emitting region NPXA adjacent to the light-emitting region PXA. The non-light emitting region NPXA may surround the light-emitting region PXA. In this embodiment, the light-emitting region PXA is defined to correspond to a partial region of the first electrode AE exposed by the opening 70-OP.

The light-emitting layer EL may be disposed on the first electrode AE. The light-emitting layer EL may be disposed in a region corresponding to the opening 70-OP. That is, the light-emitting layer EL may be formed separately into each of the pixels. When the light-emitting layer EL is formed separately into each of the pixels, the light-emitting layers EL may each emit at least one color light among blue color light, red color light, and green color light. However, an embodiment is not limited thereto, and the light-emitting layer EL may be connected to the pixels, and may also be provided in common in another embodiment. In this case, the light-emitting layer EL may provide blue color light, or may provide white color light.

The second electrode CE may be disposed on the light-emitting layer EL. The second electrode CE may have an integrated shape, and may be disposed in the plurality of pixels in common.

Although not illustrated, a hole control layer may be disposed between the first electrode AE and the light-emitting layer EL. The hole control layer may be disposed in the light-emitting region PXA and the non-light emitting region NPXA in common. The hole control layer may include a hole transport layer, and may further include a hole injection layer. An electron control layer may be disposed between the light-emitting layer EL and the second electrode CE. The electron control layer may include an electron transport layer, and may further include an electron injection layer. The electron control layer may be disposed in the light-emitting region PXA and the non-light emitting region NPXA in common. The hole control layer and the electron control layer may be formed in the plurality of pixels in common by using an open mask.

The encapsulation layer 140 may be disposed on the light-emitting element layer 130. The encapsulation layer 140 may include an inorganic layer, an organic layer, and an inorganic layer which are sequentially stacked, but the layers that constitute the encapsulation layer 140 are not limited thereto.

The inorganic layers may protect the light-emitting element layer 130 from moisture and oxygen, and the organic layer may protect the light-emitting element layer 130 from foreign matters such as dust particles. The inorganic layers may include a silicon nitride layer, a silicon oxynitride layer, a silicon oxide layer, a titanium oxide layer, an aluminum oxide layer, or the like. The organic layer may include an acrylate-based organic layer, and is not limited thereto.

The input sensing layer ISL may be formed on the display panel DP through a continuous process. In this case, the input sensing layer ISL may be represented as “being directly disposed” on the display panel DP. The wording “being directly disposed” may mean that a third component is not disposed between the input sensing layer ISL and the display panel DP. That is, an additional adhesive member may not be disposed between the input sensing layer ISL and the display panel DP.

Alternatively, the input sensing layer ISL may be provided as a separate module to be coupled to the display panel DP through an adhesive member. The adhesive member may include a typical adhesive or bonding agent.

The input sensing layer ISL may include a first sensing insulation layer 201, a first conductive layer 202, a second sensing insulation layer 203, a second conductive layer 204, and a sub-cover layer 205.

The first sensing insulation layer 201 may be an inorganic layer which includes at least any one among silicon nitride, silicon oxynitride, and silicon oxide. Alternatively, the first sensing insulation layer 201 may also be an organic layer which includes an epoxy resin, an acrylic resin, or an imide-base resin. The first sensing insulation layer 201 may have a single-layer structure, or may have a multi-layer structure laminated along the third direction DR3.

Each of the first conductive layer 202 and the second conductive layer 204 may have a single-layer structure, or may have a multi-layer structure laminated along the third direction DR3. In this embodiment, a metal layer of the single-layer structure may include molybdenum, silver, titanium, copper, aluminum, or an alloy thereof. A conductive layer of the multi-layer structure may include metal layers. For example, the metal layers may have a three-layer structure of titanium/aluminum/titanium. The conductive layer of the multi-layer structure may include at least one metal layer and at least one transparent conductive layer.

When the first conductive layer 202 and the second conductive layer 204 include a metal layer, the first conductive layer 202 and the second conductive layer 204 may be opaque. Accordingly, the first conductive layer 202 and the second conductive layer 204 may be patterned so as to overlap the non-light emitting region NPXA and not to overlap the light-emitting region PXA.

At least any one of the second sensing insulation layer 203 and the sub-cover layer 205 may include an inorganic film. The inorganic film may include at least one among aluminum oxide, titanium oxide, silicon oxide, silicon nitride, silicon oxynitride, zirconium oxide, and hafnium oxide.

At least any one of the second sensing insulation layer 203 and the sub-cover layer 205 may include an organic film. The organic film may include at least any one among an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

The first conductive layer 202 and a portion of the second conductive layer 204 may be connected through a contact hole CNT defined in the second sensing insulation layer 203.

FIG. 6 is a plan view of a display panel according to an embodiment of the invention.

Referring to FIG. 6, a display panel DP according to the invention may be divided into a first region A1, a second region A2, and a third region A3. The first to third regions A1, A2, and A3 of the display panel DP illustrated in FIG. 6 correspond to the first to third regions A1, A2, and A3 of the display module DM described with reference to FIG. 4, respectively. In this specification, the wording “a region/portion corresponds to a region/portion” means overlapping without being limited to the same area.

The display panel DP according to an embodiment may include an active region AA where a pixel PX is disposed and a peripheral region NAA adjacent to the active region AA. The active region AA and the peripheral region NAA correspond to the active region AA and the peripheral region NAA described with reference to FIG. 4, respectively.

Accordingly, the active region AA corresponds to a region, of the first region A1, where the pixel PX is disposed, and the peripheral region NAA includes the second region A2, the third region A3, and a remaining region of the first region A1 other than the region where the pixel PX is disposed.

The display panel DP may include a scan driver SDV, an emission driver EDV, a driving chip DIC in the peripheral region NAA. The driving chip DIC may be a data driver.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, and a plurality of pads PD. Here, m and n are natural numbers. The pixels PX may be connected to the scan lines SL1 to SLm, the data lines DL1 to DLn, and the emission lines EL1 to ELm.

The scan lines SL1 to SLm may extend in a first direction DR1 to be connected to the scan driver SDV. The data lines DL1 to DLn may extend in a second direction DR2 via the second region A2 from the first region A1, to be connected to the driving chip DIC disposed in the third region A3. The emission lines EL1 to ELm may extend in the first direction DR1 to be connected to the emission driver EDV.

The power line PL may include a portion extending in the second direction DR2 and a portion extending in a diagonal direction with respect to the first direction DR1 and the second direction DR2. The portion extending in the second direction DR2 and the portion extending in the diagonal direction with respect to the first direction DR1 and the second direction DR2 may be disposed on different layers. The portion extending in the second direction DR2 of the power line PL may extend to the third region A3 via the second region A2 from the first region A1. The power line PL may provide a reference voltage to the pixels PX.

The first control line CSL1 may be connected to the scan driver SDV, and may extend to the third region A3 via the second region A2 from the first region A1. The second control line CSL2 may be connected to the emission driver EDV, and may extend to the third region A3 via the second region A2 from the first region A1.

The pads PD may be disposed adjacent to an end of the third region A3. The driving chip DIC, the power line PL, the first control line CSL1, and the second control line CSL2 may be connected to the pads PD. A flexible circuit board FCB may be disposed on the display panel DP while overlapping the end of the third region A3 of the display panel DP. The flexible circuit board FCB may include pads corresponding to the pads PD, and may be electrically connected to the pads PD through an anisotropic conductive adhesive layer.

The display panel DP according to an embodiment may include a first contact hole CN-H1 defined in the first region A1. The display panel DP may include extension sensing lines TL-L extending to the third region A3 via the first region A1 and the second region A2 from the first contact hole CN-H1. The extension sensing lines TL-L may be connected to corresponding sensing lines among sensing lines TL1, TL2, and TL3 (see FIG. 7) to be described later, in a one-to-one correspondence.

FIG. 6 illustrates that the extension sensing lines TL-L are disposed between the data lines DL1 to DLn, but is not limited thereto. For another example, the data lines DL1 to DLn may be disposed between the extension sensing lines TL-L. Accordingly, the first contact hole CN-H1 may be provided in plurality with the data lines DL1 to DLn therebetween, and is not limited to any one embodiment.

FIG. 7 is a plan view of an input sensing layer according to an embodiment of the invention.

Referring to FIG. 7, an input sensing layer ISL according to an embodiment may include sensing electrodes TE1 and TE2 and sensing lines TL1, TL2, and TL3. When the input sensing layer ISL is directly disposed on the display panel DP (see FIG. 4) through a continuous process, the input sensing layer may be formed only on a region overlapping a first region A1 of the display panel DP.

The input sensing layer ISL may obtain information about an external input through a change in capacitance between first sensing electrodes TE1 and second sensing electrodes TE2. The first sensing electrodes TE1 are arranged along a first direction DR1 and each extend along a second direction DR2. The first sensing electrodes TE1 may each include a first sensing pattern SP1 and a first connection pattern BP1.

The first sensing pattern SP1 is disposed in an active region AA. The first sensing pattern SP1 may have a rhombus shape. However, this is exemplarily illustrated, and the first sensing pattern SP1 may have various shapes, and is not limited to any one embodiment.

The first connection pattern BP1 is disposed in the active region AA. The first connection pattern BP1 may be disposed between the adjacent first sensing patterns. The first connection pattern BP1 and the first sensing pattern SP1 may be disposed on different layers and connected to each other through a contact hole.

The second sensing electrodes TE2 are arranged along the second direction DR2 and each extend along the first direction DR1. The second sensing electrodes TE2 may each include a second sensing pattern SP2 and a second connection pattern BP2.

The second sensing pattern SP2 may be spaced apart from the first sensing pattern SP1. The first sensing pattern SP1 and the second sensing pattern SP2 may not be in contact, and may transmit and receive an independent electrical signal.

The second sensing pattern SP2 may have the same shape as the first sensing pattern SP1. For example, the second sensing pattern SP2 may have a rhombus shape. However, this is exemplarily illustrated, and the second sensing pattern SP2 may have various shapes and is not limited to any one embodiment.

The second connection pattern BP2 may be disposed between the adjacent second sensing patterns. For convenience of explanation, the second sensing electrode TE2 is described as being divided into the second sensing pattern SP2 and the second connection pattern BP2, but the second sensing electrode TE2 may be substantially provided as one pattern.

According to an embodiment, the first connection pattern BP1 may correspond to the first conductive layer 202 described with reference to FIG. 5. The first sensing pattern SP1, the second sensing pattern SP2, and the second connection pattern BP2 may correspond to the second conductive layer 204 described with reference to FIG. 5. That is, the second sensing electrode TE2 may be disposed at a same layer as the first sensing pattern SP1, and here, the first sensing pattern SP1 and the second sensing electrode TE2 may be provided as a plurality of mesh lines extending in respective diagonal directions of the first direction DR1 and the second direction DR2.

The sensing lines TL1, TL2, and TL3 are disposed in a peripheral region NAA. The sensing lines TL1, TL2, and TL3 may include first sensing lines TL1, second sensing lines TL2, and third sensing lines TL3.

The first sensing lines TL1 are connected to the first sensing electrodes TE1, respectively. In this embodiment, the first sensing lines TL1 are connected to lower ends among the upper and lower ends of the first sensing electrodes TE1, respectively. The second sensing lines TL2 are connected to upper ends among the upper and lower ends of the first sensing electrodes TE1, respectively. According to the invention, the first sensing electrodes TE1 may be connected to the first sensing lines TL1 and the second sensing lines TL2, respectively. Accordingly, for the first sensing electrodes TE1 which have a relatively long length compared to the second sensing electrodes TE2, sensitivity according to a region may be maintained uniformly.

This is exemplarily illustrated, and the second sensing lines TL2 may also be omitted in the input sensing layer ISL according to an embodiment of the invention, and the above configuration is not limited to any one embodiment.

The third sensing lines TL3 are connected to ends of the second sensing electrodes TE2, respectively. In this embodiment, the third sensing lines TL3 are connected to left ends among the right and left ends of the second sensing electrodes TE2, respectively.

The input sensing layer ISL may include a second contact hole CN-H2 overlapping the peripheral region NAA. The second contact hole CN-H2 may overlap the first contact hole CN-H1 (see FIG. 6) of the display panel DP (see FIG. 6). The sensing lines TL1, TL2, and TL3 may be connected to the corresponding extension sensing lines TL-L (see FIG. 6) through the second contact hole CN-H2 defined in the input sensing layer ISL and the first contact hole CN-H1 defined in the display panel DP. Accordingly, the sensing electrodes TE1 and TE2 may be electrically connected to a flexible circuit board FCB.

FIG. 8 is an enlarged cross-sectional view of a portion of an electronic apparatus according to an embodiment of the invention. Specifically, FIG. 8 illustrates a cross-sectional view of an electronic apparatus ED where a second region A2 of a display module DM is bent with respect to a virtual axis RX extending in a first direction DR1.

Referring to FIG. 8, the electronic apparatus ED may include a window WM, an optical film LF, a display module DM, a lower member LM, and a cover layer CIC.

According to an embodiment of the invention, the window WM may include a base substrate BS, a window protection layer WPL disposed on the base substrate BS, and a bezel pattern BZP disposed on a lower surface of the window protection layer WPL. The window WM may further include a window adhesive layer WAL which couples the window protection layer WPL and the base substrate BS together.

The bezel pattern BZP may define the bezel region BZA illustrated in FIG. 4. In this embodiment, the bezel pattern BZP may be disposed on one surface, which faces the base substrate BS, of the window protection layer WPL. FIG. 8 exemplarily illustrates that the bezel pattern BZP is disposed on the lower surface of the window protection layer WPL, and is not limited thereto. The bezel pattern BZP may also be disposed on an upper surface of the window protection layer WPL, or any one of an upper surface or lower surface of the base substrate BS in another embodiment.

The bezel pattern BZP may be a colored light-blocking film, and may be formed through, for example, a coating method. The bezel pattern BZP may include a base material and a dye or pigment mixed into the base material. Accordingly, a user may recognize the peripheral region NAA (see FIG. 4) of the electronic apparatus ED by a color which the bezel pattern BZP has.

The optical film LF may be disposed between the window WM and the display module DM. The window WM and the optical film LF may be coupled by a first adhesive layer AL1. The optical film LF may be disposed on a first region A1 of the display module DM.

As illustrated in FIG. 8, in the display module DM, the second region A2 may be bent along the virtual axis RX extending in the first direction DR1, and thus a third region A3 may be disposed under the first region A1. That is, the first region A1 and the third region A3 may overlap each other in a third direction DR3.

The lower member LM may include lower protection films PF1 and PF2 of the display module DM and a cover panel CP. The lower protection films PF1 and PF2 may include a first protection film PF1 disposed under the first region A1 and a second protection film PF2 disposed under the third region A3. The lower protection films PF1 and PF2 may not be disposed under the second region A2, thereby allowing the display module DM to be smoothly bent.

The cover panel CP may be disposed under the first protection film PF1. The first protection film PF1 and the cover panel CP may be coupled by a second adhesive layer AL2. As illustrated in FIG. 8, since the second region A2 of the display module DM is bent, the second protection film PF2 may be coupled to a lower part of the cover panel CP. The second protection film PF2 and the cover panel CP may be coupled by a third adhesive layer AL3. The cover panel CP may be disposed between the first protection film PF1 and the second protection film PF2 after the second region A2 of the display module DM is bent, thereby supporting the bent display module DM.

The cover layer CIC may be disposed under the display module DM. For example, the cover layer CIC may cover the entire of a driving chip DIC mounted on the third region A3, while overlapping at least a portion of the third region A3. The cover layer CIC may cover at least a portion of a flexible circuit board FCB. The invention is not limited thereto, and the cover layer CIC may continuously extend from the third region A3 to one end of the second region A2 adjacent to the first region A1 in another embodiment. According to an embodiment, the cover layer CIC may cover the entire region of the second region A2.

According to an embodiment of the invention, an air gap AG may be formed between the cover layer CIC and the display module DM. The air gap AG may be formed with a thickness, which the driving chip DIC has, during a process of forming the cover layer CIC on the driving chip DIC. A detailed description thereof will be specifically given later in a manufacturing process of the electronic apparatus ED.

The cover layer CIC according to the invention may block noise, which is made near the flexible circuit board FCB and the driving chip DIC, and may cover wirings disposed on the flexible circuit board FCB, thereby protecting against risks such as an impact provided from the outside.

Although not illustrated in FIG. 8, the electronic apparatus ED according to the invention may further include an organic layer covering the second region A2. For example, the electronic apparatus ED, in which high rigidity is required in a bending region, may further include the organic layer disposed on the second region A2 of the display module DM.

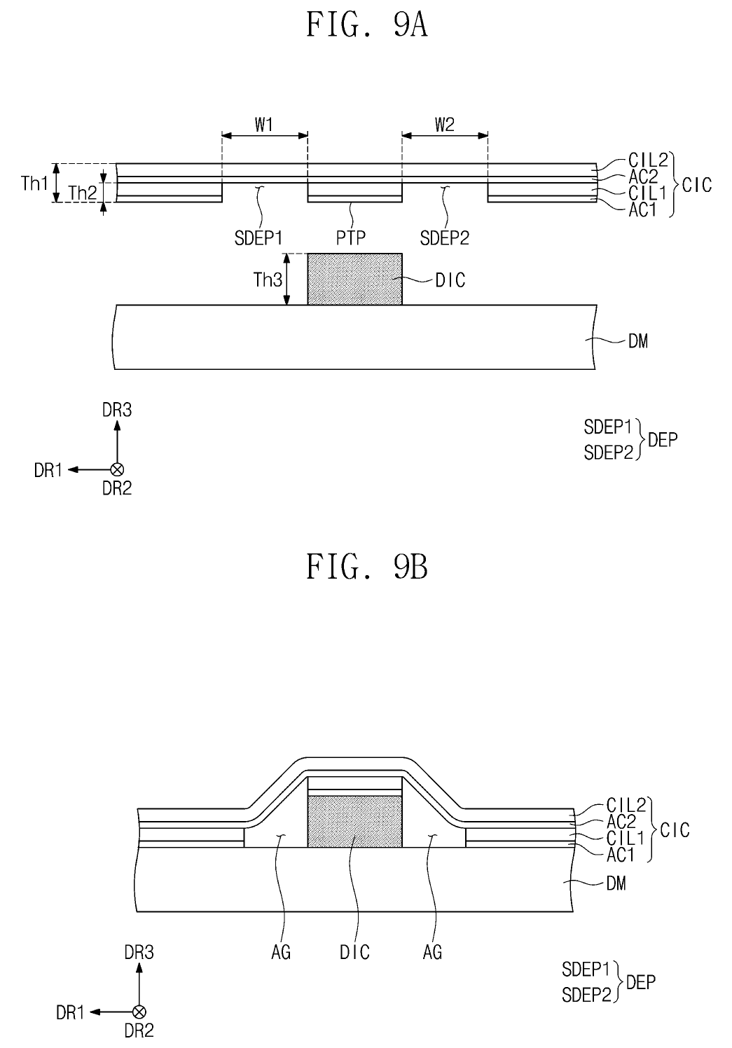

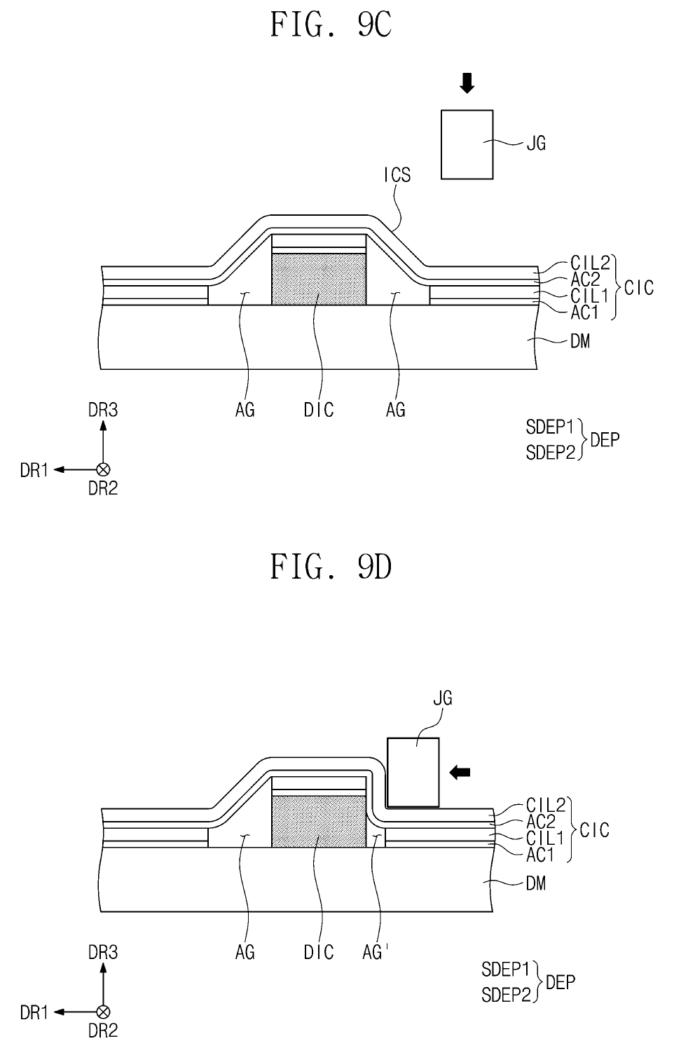

FIGS. 9A to 9D are process diagrams illustrating a part of a method for manufacturing an electronic apparatus according to an embodiment of the invention. For example, FIGS. 9A to 9D illustrate a step of bonding a cover layer CIC, which covers the driving chip DIC illustrated in FIG. 8, onto the driving chip DIC. The step of bonding the cover layer CIC onto the driving chip DIC may be performed before a display module DM is bent, as illustrated in FIG. 4. Therefore, reference directions of FIGS. 9A to 9D are the same as those in FIG. 4. However, the invention is not limited thereto, and the step of bonding the cover layer CIC onto the driving chip DIC may be performed after the display module DM is bent, as illustrated in FIG. 8 in another embodiment.

Referring to FIGS. 9A and 9B, a step of disposing the cover layer CIC on the driving chip DIC and the step of bonding the cover layer CIC to the driving chip DIC may be performed. The display module DM illustrated in FIG. 9A may correspond to the display module DM illustrated in FIG. 4, and the driving chip DIC may be disposed in a third region A3 of the display module DM. In the step of bonding the cover layer CIC to the driving chip DIC, the cover layer CIC may be bent.

Referring to FIG. 9A, the cover layer CIC may include a first cover adhesive layer AC1, a first sub-cover layer CIL1, a second cover adhesive layer AC2, and a second sub-cover layer CIL2, which are sequentially stacked. The first sub-cover layer CIL1 and the second sub-cover layer CIL2 may be coupled or bonded by the second cover adhesive layer AC2, and at a later step, the first sub-cover layer CIL1 and the driving chip DIC may be coupled or bonded by the first cover adhesive layer AC1.

According to an embodiment of the invention, the first sub-cover layer CIL1 and the second sub-cover layer CIL2 may each include a metal material with high flexibility, and the first cover adhesive layer AC1 and the second cover adhesive layer AC2 may each include an insulating adhesive. For example, the first sub-cover layer CIL1 and the second sub-cover layer CIL2 may each include copper (Cu). When each of the first sub-cover layer CIL1 and the second sub-cover layer CIL2 includes copper (Cu), a minimum thickness, which each of the first sub-cover layer CIL1 and the second sub-cover layer CIL2 should have so as to have a modulus value, may be smaller than a minimum thickness of a polymer material.

However, an embodiment is not limited thereto, and the first sub-cover layer CIL1 and the second sub-cover layer CIL2 may each include an adhesive insulating material in another embodiment. Here, the first cover adhesive layer AC1 and the second cover adhesive layer AC2 may be omitted.

According to an embodiment of the invention, a depression portion DEP that is depressed in a third direction DR3 may be defined in the cover layer CIC. The depression portion DEP may correspond to the driving chip DIC. The depression portion DEP may be formed by penetration of the first cover adhesive layer AC1 and the first sub-cover layer CIL1.

The depression portion DEP may include a first sub-depression portion SDEP1 and a second sub-depression portion SDEP2, which are spaced apart from each other in a first direction DR1. In addition, a protrusion portion PTP disposed between the first sub-depression portion SDEP1 and the second sub-depression portion SDEP2 may be defined in the cover layer CIC. The protrusion portion PTP may overlap the driving chip DIC in a plan view. A width of the protrusion portion PTP in the first direction DR1 may be the same as a width of the driving chip DIC in the first direction DR1. That is, two sides of the protrusion portion PTP may be aligned with two corresponding sides of the driving chip DIC in a plan view.

The first sub-depression portion SDEP1 may have a first width W1 in the first direction DR1, and the second sub-depression portion SDEP2 may have a second width W2 in the first direction DR1. The first width W1 and the second width W2 may be the same. Unlike what is illustrated, the first width W1 and the second width W2 may the same as a second thickness Th2. For example, the first width W1 and the second width W2 may be about 40 micrometers (μm) to about 60 μm.

The cover layer CIC according to the invention may have a first thickness Th1, and the depression portion DEP may have the second thickness Th2. The second thickness Th2 of the depression portion DEP may be equal to a sum of the respective thicknesses of the first cover adhesive layer AC1 and the first sub-cover layer CIL1. For example, the first thickness Th1 may be about 80 μm to about 120 μm, and the second thickness Th2 may be about 40 μm to about 60 μm. The driving chip DIC may have a third thickness Th3. The third thickness Th3 may be greater than the first thickness Th1. For example, the first thickness Th3 may be about 150 μm to about 200 μm. Referring to FIGS. 9A and 9B together, in the step of bonding the cover layer CIC onto the driving chip DIC, space may be made at the two sides of the driving chip DIC, which may cause air bubbles, or the like. Since the first sub-depression portion SDEP1 and the second sub-depression portion SDEP2, which correspond to the driving chip DIC, are defined in the cover layer CIC according to the invention, an air gap AG may be made between the driving chip DIC and the cover layer CIC, but the air gap AG may be minimized to reduce occurrence of air bubbles between the driving chip DIC and the cover layer CIC. In addition, occurrence of wrinkles on a side surface of the cover layer CIC may be prevented. As a result, the electronic apparatus ED (see FIG. 4) with reliability may be provided.

Referring to FIGS. 9C and 9D, a step of disposing a jig JG on the cover layer CIC and a step of moving the jig JG toward the driving chip DIC may be performed.

Referring to FIG. 9C, the jig JG may not overlap the driving chip DIC in a plan view. The jig JG may be disposed on a region not overlapping the air gap AG. The jig JG may be disposed above the cover layer CIC, and may move in a direction opposite to the third direction DR3 to be directly disposed on the cover layer CIC. In the process where the jig JG is directly disposed on the cover layer CIC, adhesion between the cover layer CIC and the display module DM may be enhanced.

Then, referring to FIG. 9D, the jig JG may move in the first direction DR1 that is the direction where the driving chip DIC is disposed. The jig JG may apply force to the cover layer CIC in the first direction DR1 such that a lower surface of the second sub-depression portion SDEP2 (see FIG. 9A) becomes in contact with a side surface of the driving chip DIC. As a result, a size of an air gap AG' between the driving chip DIC and the cover layer CIC may be minimized to reduce occurrence of air bubbles between the driving chip DIC and the cover layer CIC. In addition, a slope surface ICS of the cover layer CIC illustrated in FIG. 9C may be removed, and thus wrinkles, which may be generated by the slope surface ICS of the cover layer CIC, may be removed. As a result, the electronic apparatus ED (see FIG. 4) with reliability may be provided.

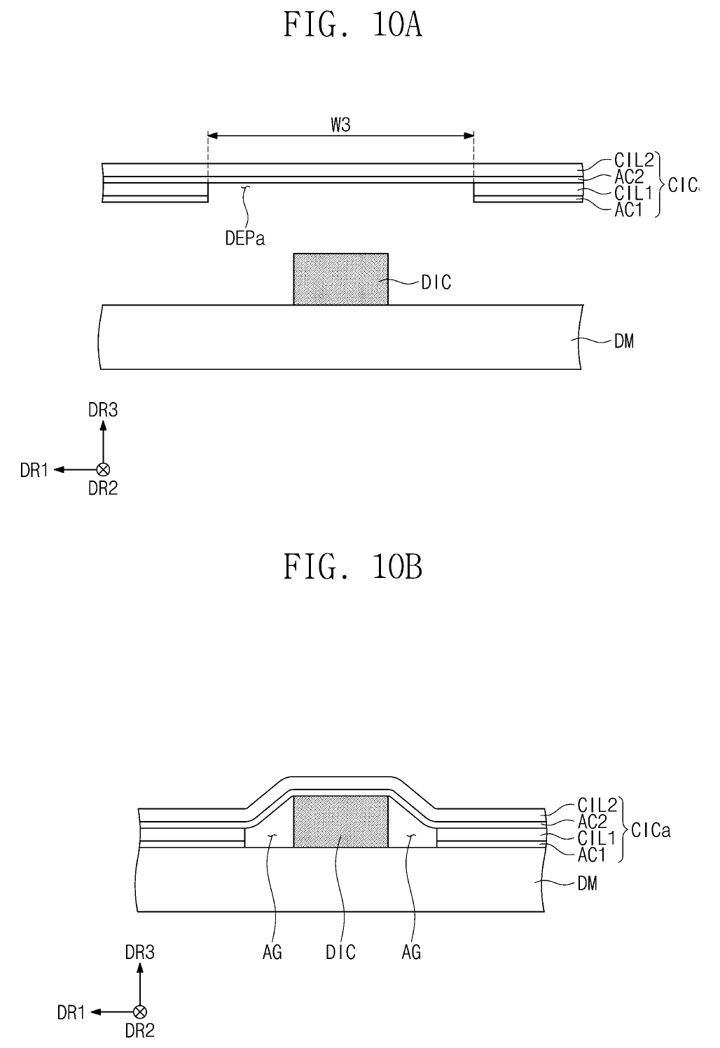

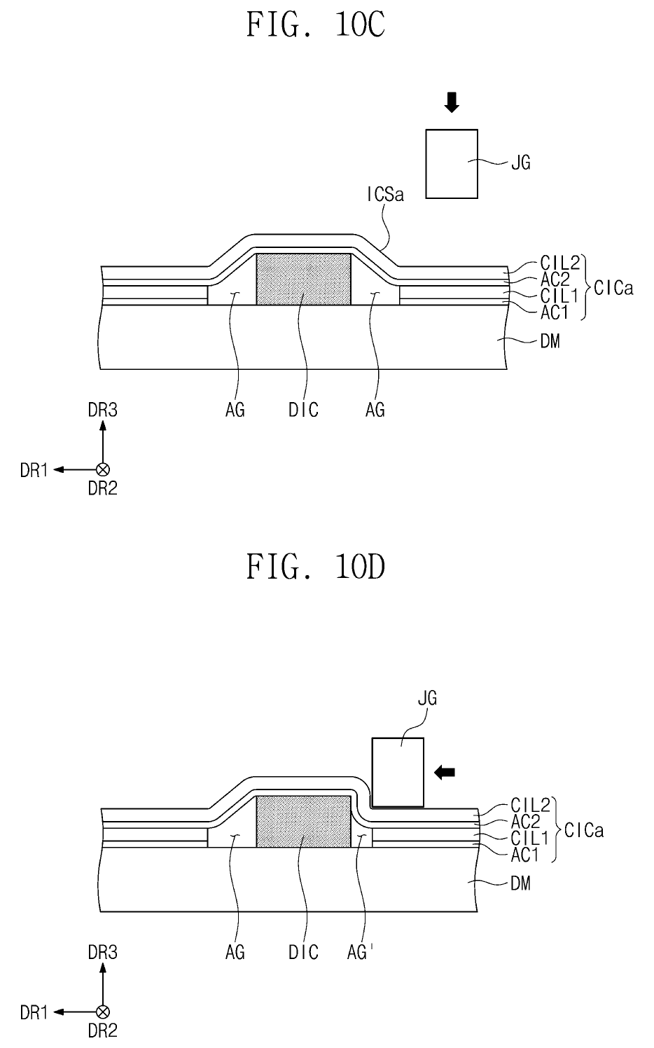

FIGS. 10A to 10D are process diagrams illustrating a part of a method for manufacturing an electronic apparatus according to another embodiment of the invention. A duplicate explanation of what has been explained above will be omitted.

Referring to FIGS. 10A and 10B, a step of disposing a cover layer CICa on a driving chip DIC and a step of bonding the cover layer CICa to the driving chip DIC may be performed.

According to an embodiment of the invention, a depression portion DEPa that is depressed in a third direction DR3 may be defined in the cover layer CICa. The depression portion DEPa may correspond to the driving chip DIC. The depression portion DEPa may be formed by penetration of a first cover adhesive layer AC1 and a first sub-cover layer CIL1.

The depression portion DEPa may overlap the driving chip DIC in a plan view. The depression portion DEPa may have a third width W3 in a first direction DR1. The depression portion DEPa may be formed through an etching process before the cover layer CICa is disposed on the driving chip DIC. An air gap AG may be formed in the step of disposing the cover layer CICa on the driving chip DIC.

Referring to FIGS. 10C and 10D, a step of disposing a jig JG on the cover layer CICa and a step of moving the jig JG toward the driving chip DIC may be performed. The steps in progress shown in FIGS. 10C and 10D may be the same as the steps in progress shown in FIGS. 9C and 9D. Accordingly, a detailed description thereof will be omitted.

In FIGS. 10C and 10D, since the jig JG moves in the first direction DR1 that is the direction where the driving chip DIC is disposed, a size of an air gap AG' between the driving chip DIC and the cover layer CICa may be minimized to reduce occurrence of air bubbles between the driving chip DIC and the cover layer CICa. In addition, a slope surface ICSa of the cover layer CICa illustrated in FIG. 10C may be removed, and thus wrinkles, which may be generated by the slope surface ICSa of the cover layer CICa, may be removed. As a result, the electronic apparatus ED (see FIG. 4) with reliability may be provided.

In a step of bonding a cover layer onto a driving chip, an air gap may be made at two sides of the driving chip, which may cause air bubbles, or the like. Since a depression portion corresponding to the driving chip is defined in the cover layer, a size of the air gap between the driving chip and the cover layer may be minimized to reduce occurrence of air bubbles between the driving chip and the cover layer. In addition, occurrence of wrinkles on a side surface of the cover layer may be prevented, and thus an electronic apparatus with reliability may be provided.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later.

Therefore, the technical scope of the invention is not to be limited to the contents stated in the detailed description of the specification, but should be determined by the claims.

What is claimed is:

1. An electronic apparatus comprising:
a display module divided into a first region including a pixel, a second region bent with respect to a virtual axis extending in a first direction, and a third region where a driving chip electrically connected to the pixel is mounted;
a flexible circuit board disposed in at least a portion of the third region of the display module and connected to the display module; and
a cover layer configured to cover the driving chip,
wherein a depression portion corresponding to the driving chip is defined in a surface of the cover layer facing the driving chip.

2. The electronic apparatus of claim 1, wherein the depression portion comprises a first sub-depression portion and a second sub-depression portion, which are located in opposite sides of the driving chip in a second direction crossing the first direction in a plan view.

3. The electronic apparatus of claim 2, wherein the cover layer comprises a protrusion portion defined between the first sub-depression portion and the second sub-depression portion.

4. The electronic apparatus of claim 3, wherein the protrusion portion overlaps the driving chip in the plan view, and
a width of the protrusion portion in the second direction is the same as a width of the driving chip in the second direction.

5. The electronic apparatus of claim 2, wherein a width of the first sub-depression portion in the second direction is the same as a width of the second sub-depression portion in the second direction in a status that the cover layer is unbent.

6. The electronic apparatus of claim 1, wherein the depression portion overlaps the driving chip in a plan view.

7. The electronic apparatus of claim 6, wherein a width of the depression portion in a second direction crossing the first direction is greater than a width of the driving chip in the second direction in a status that the cover layer is unbent.

8. The electronic apparatus of claim 1, wherein the cover layer comprises a first cover adhesive layer, a first sub-cover layer disposed on the first cover adhesive layer, a second cover adhesive layer disposed on the first sub-cover layer, and a second sub-cover layer disposed on the second cover adhesive layer.

9. The electronic apparatus of claim 8, wherein each of the first sub-cover layer and the second sub-cover layer comprises a metal material, and
each of the first cover adhesive layer and the second cover adhesive layer comprises an insulating adhesive.

10. The electronic apparatus of claim 8, wherein the depression portion is formed by penetration of the first cover adhesive layer and the first sub-cover layer.

11. The electronic apparatus of claim 1, wherein a maximum thickness of the cover layer is about 40 μm to about 80 μm in a status that the cover layer is unbent.

12. The electronic apparatus of claim 1, wherein a thickness of the driving chip is about 150 μm to about 200 μm.

13. The electronic apparatus of claim 1, wherein the cover layer covers at least a portion of the flexible circuit board.

14. The electronic apparatus of claim 1, further comprising a processor configured to provide image data to the display module, wherein the display module is configured to display an image based on the image data.

15. A method for manufacturing an electronic apparatus, the method comprising:
forming a display module, which is divided into a first region including a pixel, a second region bent with respect to a virtual axis extending in a first direction, and a third region where a driving chip electrically connected to the pixel is mounted;
forming a flexible circuit board electrically connected to the display module on one side of the third region of the display module;
disposing the flexible circuit board on a rear surface of the display module by bending the second region; and
disposing, on the driving chip, a cover layer which covers the driving chip,
wherein a depression portion corresponding to the driving chip is defined in a surface of the cover layer facing the driving chip.

16. The method of claim 15, further comprising bonding the cover layer to the driving chip after the disposing of the cover layer.

17. The method of claim 16, wherein the bonding of the cover layer to the driving chip comprises:
disposing a jig in a region spaced apart from the driving chip in a second direction crossing the first direction; and
moving the jig toward the driving chip.

18. The method of claim 17, wherein after moving of the jig toward the driving chip, the cover layer is in contact with a side surface of the driving chip.

19. The method of claim 15, wherein the depression portion comprises a first sub-depression portion and a second sub-depression portion, which are located in opposite sides of the driving chip in a second direction crossing the first direction in a plan view.

20. The method of claim 15, wherein the depression portion overlaps the driving chip in a plan view, and
a width of the depression portion in a second direction crossing the first direction is greater than a width of the driving chip in the second direction in a status that the cover layer is unbent.
